(19) United States
(12) Patent Application Publication
(10) Pub. No.: US 2016/0027783 A1
(43) Pub. Date: Jan. 28, 2016

(54) PRODUCTION METHOD FOR SEMICONDUCTOR DEVICE

(71) Applicant: PS4 LUXCO S.A.R.L., Luxembourg (LU)

(72) Inventor: Katsumi Koge, Tokyo (JP)

(21) Appl. No.: 14/774,700

(22) PCT Filed: Mar. 10, 2014
(86) PCT No.: PCT/JP2014/056719

§ 371 Date: Sep. 10, 2015

(30) Foreign Application Priority Data
Mar. 15, 2013 (JP) 2013-053895

(51) Int. Cl. H01L 27/108; H01L 49/02

(52) U.S. Cl. CPC H01L 27/1087; H01L 28/91; H01L 28/92

(57) ABSTRACT

One production method for semiconductor devices includes sequentially forming a stopper film and a BPSG film, forming a cylinder etch laminated mask upon the BPSG film, forming openings having a prescribed pattern in the cylinder etch laminated mask, then, using same as a mask, forming a cylinder hole that pierces from the BPSG film to the stopper film in the thickness direction. Next, forming a conductive layer that adjoins the side surfaces of the BPSG film, the stopper film, and a polysilicon film being part of the cylinder etch laminated mask, then removing the polysilicon film and the BPSG film .

### TECHNICAL FIELD

The present invention relates to a method for manufacturing a semiconductor device, and more particularly to a method in which holes having a large aspect ratio are formed in an insulating layer covering a semiconductor substrate.

### BACKGROUND

As semiconductor devices have come to have increasingly more components packed into increasingly small packages in recent years, a need has arisen for a process in which holes having a large aspect ratio are formed in the insulating layer covering the semiconductor substrate. For example, Patent Document 1 discloses a process for manufacturing a representative example of a semiconductor memory device (a dynamic random access memory (DRAM) device) in which cylindrical holes for forming cell capacitors are formed in a cylinder interlayer film (see Patent Document 1).

As the area available for each cell capacitor has decreased in recent years with the increasing miniaturization and the increasing number of components integrated into DRAM devices, the cylinder interlayer film must be formed with a greater film thickness. This causes the aspect ratio of the cylindrical holes formed in the cylinder interlayer film to become extremely large, thereby presenting various problems in the process for forming those cylindrical holes. For example, such devices are prone to material removal defects due to insufficient etching as well as shape defects such as bowing.

### RELATED ART DOCUMENT

### Patent Document

Patent Document 1: Japanese Patent Application Laid-Open Publication No. 2007-180493

### SUMMARY OF THE INVENTION

### Problems to be Solved by the Invention

Conventional methods for preventing such defects include using a multilayer cylinder interlayer film, adding a bowing prevention sidewall film, using a multistep etching process, and the like. However, each of these conventional methods entails an increased number of steps in the manufacturing process and makes it difficult to form patterns small enough to necessitate double-patterning of patterns below the limits of lithography resolution.

### Means for Solving the Problems

One aspect of the present invention is a method for manufacturing a semiconductor device, including: forming a first insulating layer and a second insulating layer in order; forming a mask layer on top of the second insulating layer; forming openings in a prescribed pattern in the mask layer; forming holes going through the second insulating layer to the first insulating layer in a thickness direction thereof, using the mask layer as a mask; forming conductive layers contacting side surfaces of the mask layer, the second insulating layer, and the first insulating layer; and removing the mask layer and the second insulating layer.

Another aspect of the present invention is a method for manufacturing a semiconductor device, including: forming a first insulating layer and a second insulating layer in order; forming a first support layer on top of the second insulating layer; forming, in a first pattern in the first support layer, openings that expose portions of the second insulating layer; forming a first mask layer covering the first support layer and exposed portions of the second insulating layer; forming, in the first mask layer and in a prescribed pattern, openings that overlap at least partially with the first pattern; forming holes going through the first support layer and the second insulating layer to the first insulating layer in a thickness direction thereof, using the first mask layer as a mask; forming conductive layers contacting side surfaces of the first mask layer, the first support layer, the second insulating layer, and the first insulating layer; and removing the first mask layer and the second insulating layer.

Yet another aspect of the present invention is a method for manufacturing a semiconductor device, including: forming a first insulating layer and a second insulating layer in order; forming a first support layer on top of the second insulating layer; forming, in a first pattern in the first support layer, openings that expose portions of the second insulating layer; forming a first mask layer covering the first support layer and exposed portions of the second insulating layer; forming a second support layer on top of the first mask layer; forming, in a second pattern in the second support layer, openings that expose portions of the first mask layer; forming a second mask layer covering the second support layer and exposed portions of the first mask layer; forming, in a prescribed pattern, openings that overlap at least partially with the first pattern and the second pattern and that go through the second mask layer and the second support layer to the first mask layer in a thickness direction thereof; forming holes going through the first support layer and the second insulating layer to the first insulating layer in a thickness direction thereof, using the second mask layer as a mask; forming conductive layers contacting side surfaces of the second support layer, the second mask layer, the first mask layer, the first support layer, the second insulating layer, and the first insulating layer; and removing the second mask layer, the first mask layer, and the second insulating layer.

### Effects of the Invention

The present invention makes it possible to reduce the aspect ratio of the holes by using a mask layer and a conductive layer for patterning the first and second insulating layer as-is as a sidewall. This not only reduces the overall etching time but also reduces the occurrence of removal defects and bowing, thereby making it possible to increase yield.

### BRIEF DESCRIPTION OF THE DRAWINGS

FIG. 1 is a cross-sectional view illustrating a method for manufacturing a semiconductor device according to Embodiment 1 of the present invention. FIG. 1(a) illustrates the semiconductor device prior to patterning, and FIG. 1(b) illustrates the device after patterning.

FIG. 2 is a cross-sectional view illustrating one step of the method for manufacturing a semiconductor device according to Embodiment 1.

FIG. 3 is a cross-sectional view illustrating one step of the method for manufacturing a semiconductor device according to Embodiment 1.

FIG. 4 is a cross-sectional view illustrating one step of the method for manufacturing a semiconductor device according to Embodiment 1.

FIG. 5 is a cross-sectional view illustrating one step of the method for manufacturing a semiconductor device according to Embodiment 1.

FIG. 6 is a cross-sectional view illustrating a method for manufacturing a semiconductor device according to Embodiment 2 of the present invention. FIG. 6(a) illustrates the semiconductor device prior to patterning, and FIG. 6(b) illustrates the device after patterning.

FIG. 7 is a cross-sectional view illustrating one step of the method for manufacturing a semiconductor device according to Embodiment 2.

FIG. 8 is a cross-sectional view illustrating one step of the method for manufacturing a semiconductor device according to Embodiment 2.

FIG. 9 is a cross-sectional view illustrating one step of the method for manufacturing a semiconductor device according to Embodiment 2.

FIG. 10 is a cross-sectional view illustrating one step of the method for manufacturing a semiconductor device according to Embodiment 2.

FIG. 11 is a cross-sectional view illustrating a method for manufacturing a prototype semiconductor device. FIG. 11(a) illustrates the semiconductor device prior to patterning, and FIG. 11(b) illustrates the device after patterning.

### DETAILED DESCRIPTION OF EMBODIMENTS

Preferred embodiments of the present invention will be described in detail below. However, first the problems that arise when forming holes having a large aspect ratio in an insulating layer will be described.

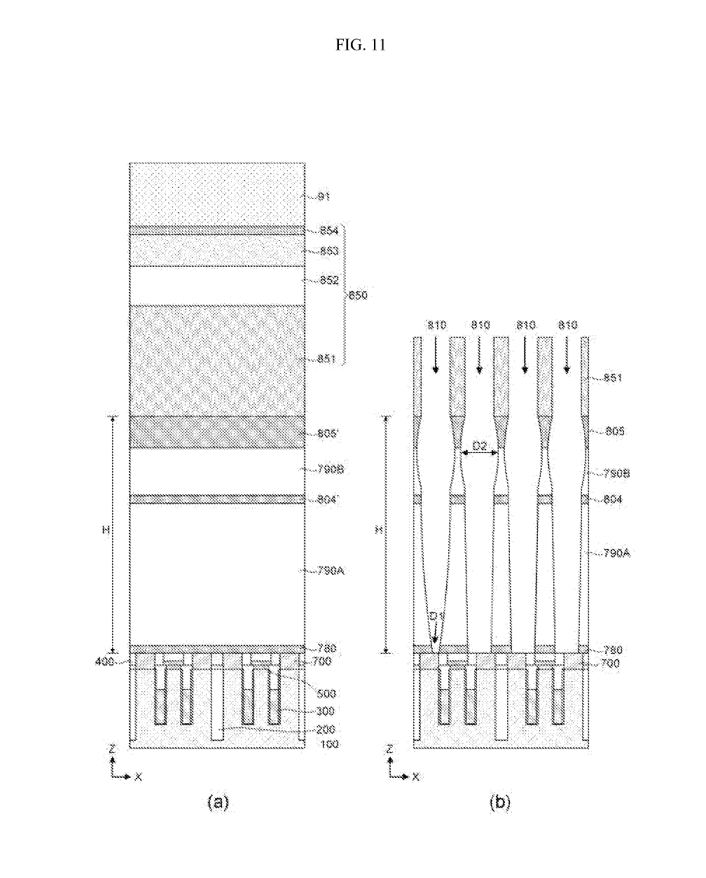

FIG. 11 is a cross-sectional view illustrating a method for manufacturing a prototype semiconductor device. FIG. 11(a) illustrates the semiconductor device prior to patterning, and FIG. 11(b) illustrates the device after patterning.

As illustrated in FIG. 11(a), a semiconductor substrate 100 includes active regions separated by an element isolation region 200. Each active region includes two word lines 300. These word lines 300 function as the gate electrodes of the cell transistors of the DRAM device. In each cell transistor, one of the source region and the drain region is connected to a bit line 500, and the other is connected to a capacitive contact plug 700 that serves as an underlying structure. The capacitive contact plug 700 is connected to the lower electrode of a cell capacitor. The capacitive contact plug 700 is formed by filling in a contact hole formed in an interlayer insulating layer 400 with a conductive film.

Once this cell transistor structure is formed, a stopper film 780, a BPSG film 790A, an Si₃N₄ film 804′, an SiO₂ film 790B, an Si₃N₄ film 805′, and a cylinder etching mask 850 are layered in order covering the cell transistor. The cylinder etching mask 850 includes a polysilicon film 851, an SiO₂ film 852, an amorphous carbon film 853, and a multilayer SiN/SiON film 854 layered in order. Here, the layered films from the stopper film 780 to the Si₃N₄ film 805′ are used to form sidewalls for forming a conductive layer (the lower electrode of the cell capacitor) in a later process. The collective height of these layered films is determined by the height H required for the conductive layer.

Next, a photoresist 91 is formed on top of these layered films, and the desired pattern is formed in the photoresist 91 using photolithography. Then, the cylinder etching mask 850 is patterned using this patterned photoresist 91 as a mask. Furthermore, the Si₃N₄ film 805′, the SiO₂ film 790B, the Si₃N₄ film 804′, the BPSG film 790A, and the stopper film 780 are etched using this patterned cylinder etching mask 850 as a mask. As illustrated in FIG. 11(b), this process forms cylindrical holes 810 that expose the capacitive contact plugs 700.

However, in the process depicted in FIGS. 11(a) and 11(b), the layered films (805′ to 780) must be etched through the entire collective height H thereof. This causes the aspect ratio of the holes to become extremely large during the etching process. As a result, the device is prone to removal defects such as that indicated by D1 in the figure and bowing defects such as those indicated by D2 in the figure, thereby decreasing the yield of the manufacturing method.

However, the method for manufacturing a semiconductor device according to the following embodiments of the present invention solves these problems.

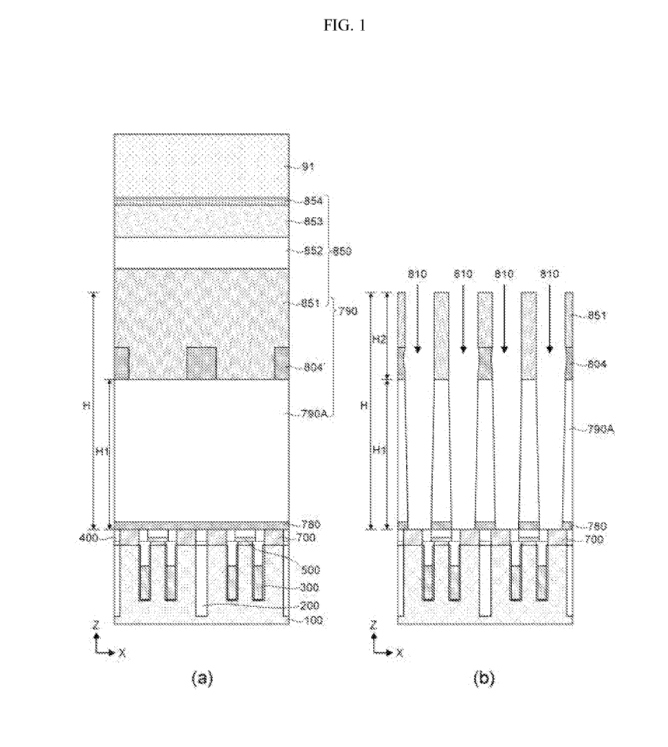

FIG. 1 is a cross-sectional view illustrating a method for manufacturing a semiconductor device according to Embodiment 1 of the present invention. FIG. 1(a) illustrates the semiconductor device prior to patterning, and FIG. 1(b) illustrates the device after patterning. Note that in the figures described below, the same reference characters are used for components that are the same as those illustrated in FIGS. 11(a) and 11(b), and redundant descriptions of those components are omitted here.

As illustrated in FIG. 1(a), in the present embodiment a stopper film 780, a BPSG film 790A, an Si₃N₄ film 804′, and a cylinder etching mask 850 are layered in order covering a cell transistor. The cylinder etching mask 850 includes a polysilicon film 851, an SiO₂ film 852, an amorphous carbon film 853, and a multilayer SiN/SiON film 854 layered in order.

Here, the stopper film 780 and the BPSG film 790A are used to form portions of sidewalls for forming a conductive layer in a later process. The collective height H1 of the stopper film 780 and the BPSG film 790A is less than the height H required for the conductive layer (the lower electrode of the cell capacitor). The polysilicon film 851 is arranged at the uppermost position of the portions that form the height H.

Next, a photoresist 91 is formed on top of these layered films, and the desired pattern is formed in the photoresist 91 using photolithography. The portions of the photoresist 91 that are removed during this patterning process are the regions where cylindrical holes 810 will be formed in a later process. Next, the cylinder etching mask 850 is patterned using this patterned photoresist 91 as a mask, thereby exposing the regions of the BPSG film 790A where the cylindrical holes 810 will be formed. At this time, the polysilicon film 851 of the cylinder etching mask 850 remains with a prescribed height H2+α in the regions where the cylindrical holes 810 will not be formed.

Next, as illustrated in FIG. 1(b), the BPSG film 790A and the stopper film 780 are etched using the patterned cylinder etching mask 850 as a mask to form the cylindrical holes 810 that expose capacitive contact plugs 700. During this process, the film thickness of the polysilicon film 851 is reduced by a and becomes equal to H2.

In the method for manufacturing a semiconductor device of the present embodiment, etching the stopper film 780 and the BPSG film 790A (which have a collective height H1 that is less than the overall required height H) in this manner reduces the aspect ratio of the holes in comparison with the prototype illustrated in FIG. 11. The patterned cylinder etching mask 850 adds a height H2, which forms the remainder of the required height H. This configuration prevents removal defects and bowing, thereby making it possible to improve yield.

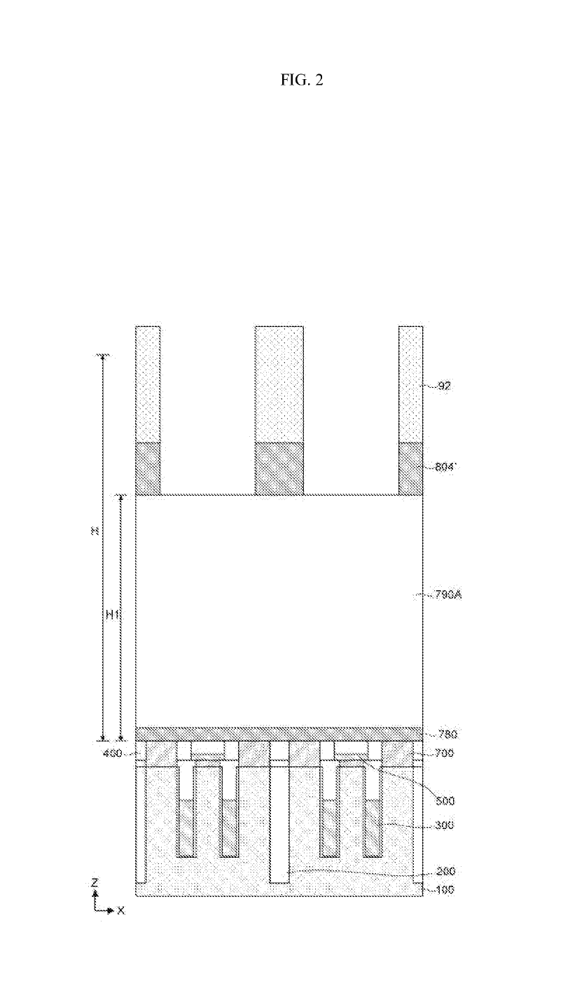

Next, the method for manufacturing a semiconductor device according to the present embodiment will be described in more detail with reference to FIGS. 2 to 5.

First, as illustrated in FIG. 2, the stopper film 780, the BPSG film 790A, the Si₃N₄ film 804′, and a photoresist 92 are layered in order covering the cell transistor. The stopper film 780 is made from silicon nitride and has a thickness of 25 nm, for example. Moreover, the BPSG film 790A has a thickness of 900 nm, and the Si₃N₄ film 804′ has a thickness of 200 nm, for example As described above, the collective film thickness (height) H1 of the stopper film 780 and the BPSG film 790A is less than the height H required for the conductive layer (the lower electrode of the cell capacitor).

Next, the desired pattern is formed in the photoresist 92 using photolithography. Then, the Si₃N₄ film 804′ is patterned using the patterned photoresist 92 as a mask to form a first support film 804 made from silicon nitride. Note that formation of the first support film 804 is not required in the present invention. However, forming the first support film 804 is extremely effective for preventing collapse of the cylindrical conductive layers that will be described later.

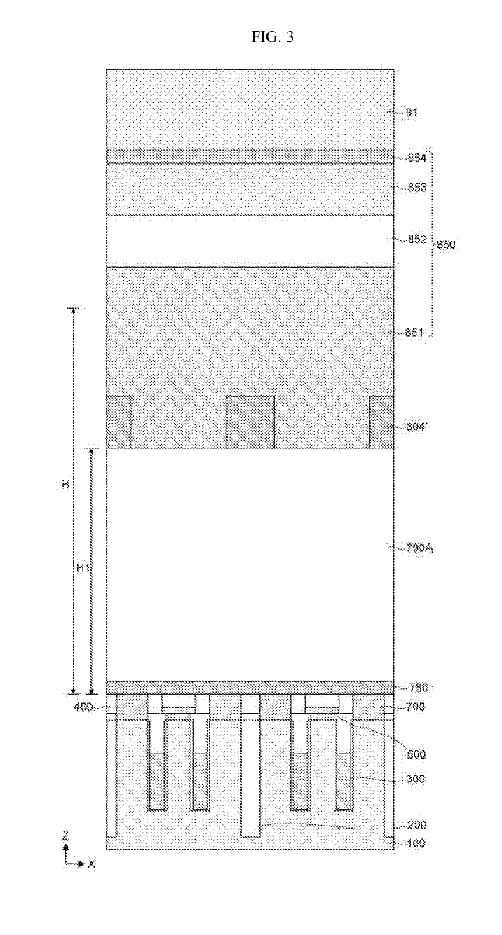

Next, as illustrated in FIG. 3, the photoresist 92 is removed, and the cylinder etching mask 850 is formed over the entire surface covering the first support film 804 and the exposed BPSG film 790A. As described above, the cylinder etching mask 850 includes the polysilicon film 851, the SiO₂ film 852, the amorphous carbon film 853, and the multilayer SiN/SiON film 854 layered in order. The polysilicon film 851 has a thickness of 500 nm, the SiO₂ film 852 has a thickness of 200 nm, and the amorphous carbon film 853 has a thickness of 200 nm, for example Moreover, the multilayer SiN/SiON film 854 includes an Si₃N₄ film and an SiON film both having a thickness of 15 nm, for example

Next, a photoresist 91 is formed on top of the cylinder etching mask 850, and the desired pattern is formed in the photoresist 91 using photolithography. The portions of the photoresist 91 that are removed during this patterning process are the regions where cylindrical holes 810 will be formed in a later process. Next, the cylinder etching mask 850 is patterned using this patterned photoresist 91 as a mask, thereby exposing the regions of the BPSG film 790A where the cylindrical holes 810 will be formed. At this time, a portion of the Si₃N₄ film 804′ is also removed, thereby forming the first support film 804.

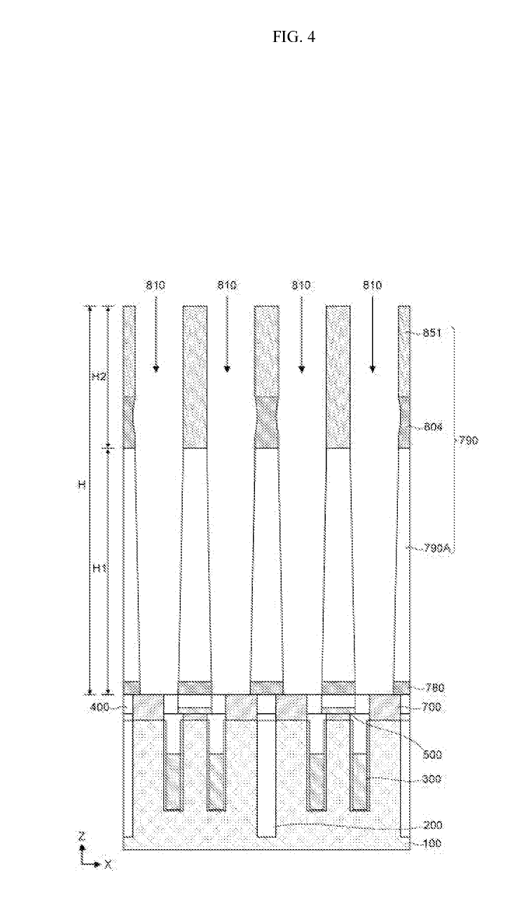

Next, as illustrated in FIG. 4, the BPSG film 790A and the stopper film 780 are etched using the patterned cylinder etching mask 850 as a mask to form the cylindrical holes 810 that expose the capacitive contact plugs 700. As illustrated in FIG. 4, etching the stopper film 780 and the BPSG film 790A (which have a collective height H1) in this manner reduces the aspect ratio of the holes in comparison with the prototype illustrated in FIG. 11. The patterned cylinder etching mask 850 adds a height H2, which forms the remainder of the required height H.

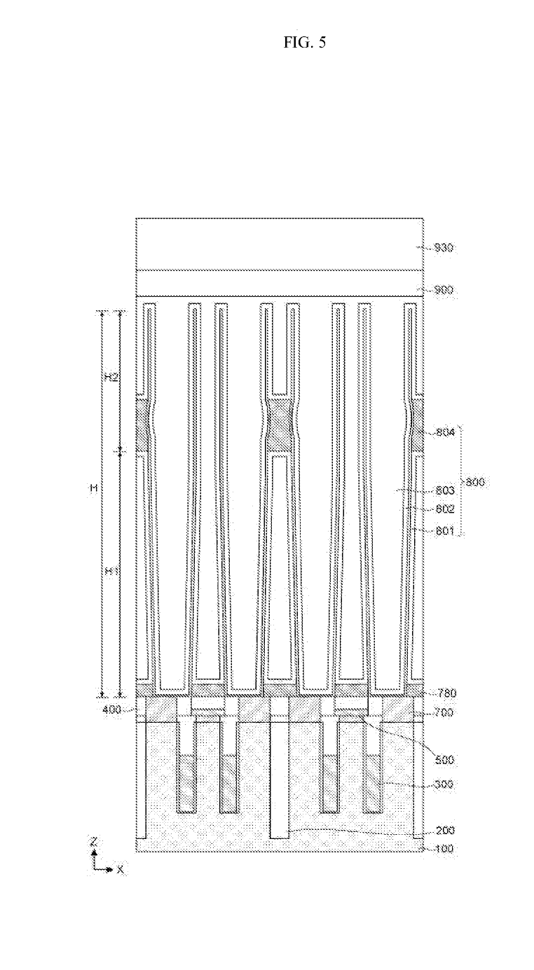

Next, a conductive layer is formed over the entire surface to cover the inner walls and bottom surfaces of the cylindrical holes 810 as well as the top surface of the polysilicon film 851 with a conductive film. Here, the inner walls of the cylindrical holes 810 include the sidewalls of the stopper film 780, the sidewalls of the BPSG film 790A, the sidewalls of the first support film 804, and the sidewalls of the polysilicon film 851. Next, the conductive film covering the top surface of the polysilicon film 851 is removed, and the polysilicon film 851 and the BPSG film 790A are removed. As illustrated in FIG. 5, this process leaves conductive layers 801 having a height H from the capacitive contact plugs 700 at the bottom. The conductive layers 801 are cylindrical and function as the lower electrodes of the cell capacitor. The conductive layers 801 have an extremely large aspect ratio but are partially supported by the first support film 804 and are thereby prevented from collapsing.

Next, after forming a capacitive insulating film 802 and upper electrodes 803, an interlayer insulating film 900 and a protective insulating film 930 are formed to complete the semiconductor device according to the present embodiment.

In the method for manufacturing a semiconductor device of the present embodiment, the stopper film 780 and the BPSG film 790A, which have a collective height H1 that is less than the overall height H required for the conductive layers 801 (the lower electrodes) are etched using the cylinder etching mask 850 (the etching mask for the stopper film 780 and the BPSG film 790A) as-is for the height H2, which forms the remainder of the required height H. In this way, the aspect ratio of the holes created during the etching process is reduced, thereby making it possible to prevent removal defects and bowing as well as to reduce the overall etching time. Moreover, after the cylindrical holes 810 are formed, an additional step for removing the polysilicon film 851 that was used as a mask is not required, thereby reducing the number of steps in the process.

Next, Embodiment 2 of the present invention will be described.

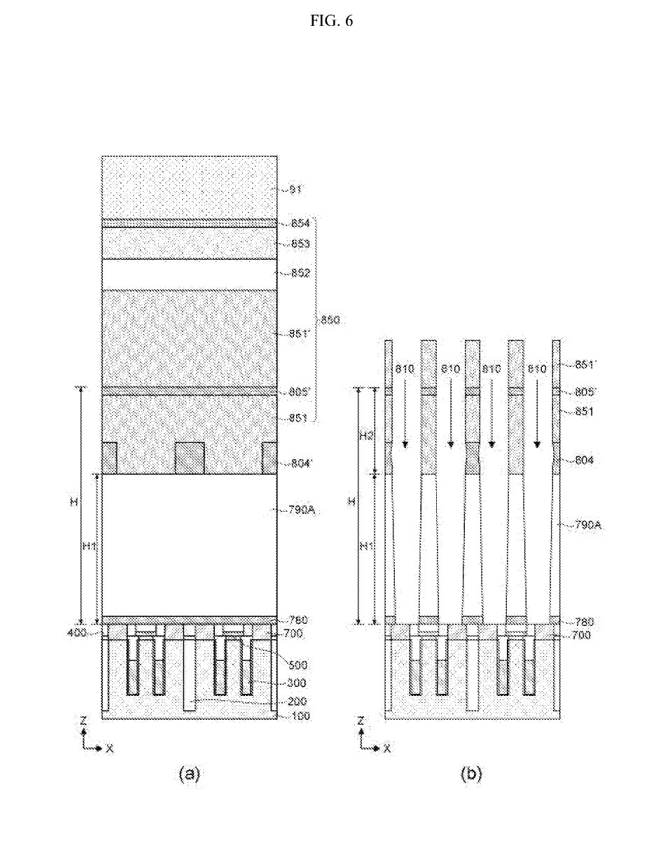

FIG. 6 is a cross-sectional view illustrating a method for manufacturing a semiconductor device according to Embodiment 2 of the present invention. FIG. 6(a) illustrates the semiconductor device prior to patterning, and FIG. 6(b) illustrates the device after patterning. Note that in the figures described below, the same reference characters are used for components that are the same as those illustrated in FIGS. 1(a) and 1(b), FIGS. 2 to 5, and FIGS. 11(a) and 11(b), and redundant descriptions of those components are omitted here.

As illustrated in FIG. 6(a), the present embodiment differs from Embodiment 1 in that the polysilicon film 851 is divided into a polysilicon film 851 and a polysilicon film 851′ and an Si₃N₄ film 805′ is formed therebetween. The Si₃N₄ film 805′ serves as a second support film 805 during later processes, and the upper surface of the Si₃N₄ film 805′ is positioned at the uppermost position of the height H from the capacitive contact plugs 700. In the present embodiment, the stopper film 780 and the BPSG film 790A have a collective film thickness of H1. Note that after forming the Si₃N₄ film 805′, the Si₃N₄ film 805′ may be patterned to form the second support film 805 before forming the polysilicon film 851′.

In the present embodiment, the polysilicon film 851, the Si₃N₄ film 805′, and the polysilicon film 851 are used as a mask when forming the cylindrical holes 810. The polysilicon film 851′ is then removed, and the Si₃N₄ film 805′ is partially removed to form the second support film 805. In the present embodiment, etching the stopper film 780 and the BPSG film 790A (which have a collective height H1 that is less than the overall required height H) in this manner reduces the aspect ratio of the holes formed during the etching process. This prevents removal defects and bowing, thereby making it possible to improve yield.

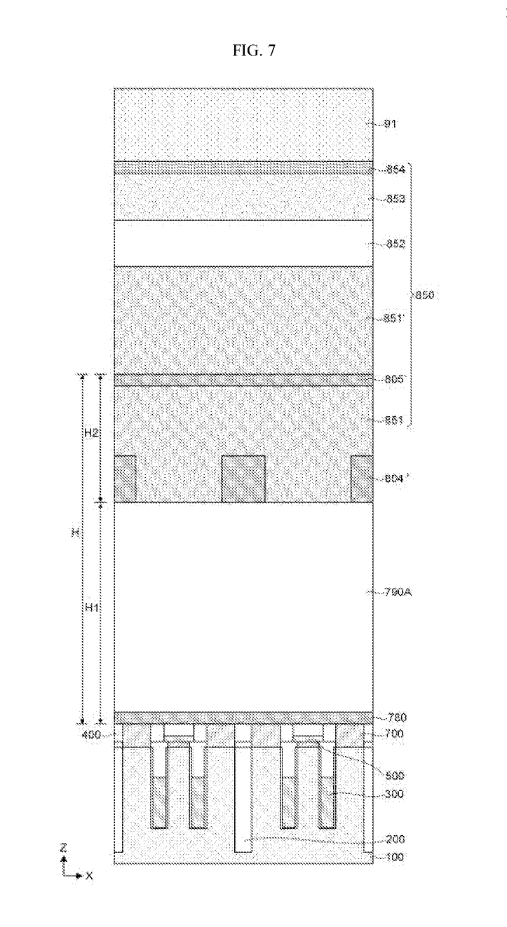

Next, the method for manufacturing a semiconductor device according to the present embodiment will be described in more detail with reference to FIGS. 7 to 10.

First, as illustrated in FIG. 7, after performing the process described in reference to FIG. 2, the cylinder etching mask 850 is formed over the entire surface covering the first support film 804 formed from portions of the Si₃N₄ film 804′ as well as the exposed BPSG film 790A. As described above, the cylinder etching mask 850 includes the polysilicon film 851, the Si₃N₄ film 805′, the polysilicon film 851′, the SiO₂ film 852, the amorphous carbon film 853, and the multilayer SiN/SiON film 854 layered in order. The total film thickness of the polysilicon film 851 and the polysilicon film 851′ is 500 nm, for example. Moreover, the Si₃N₄ film 805 has a thickness of 30 nm, for example

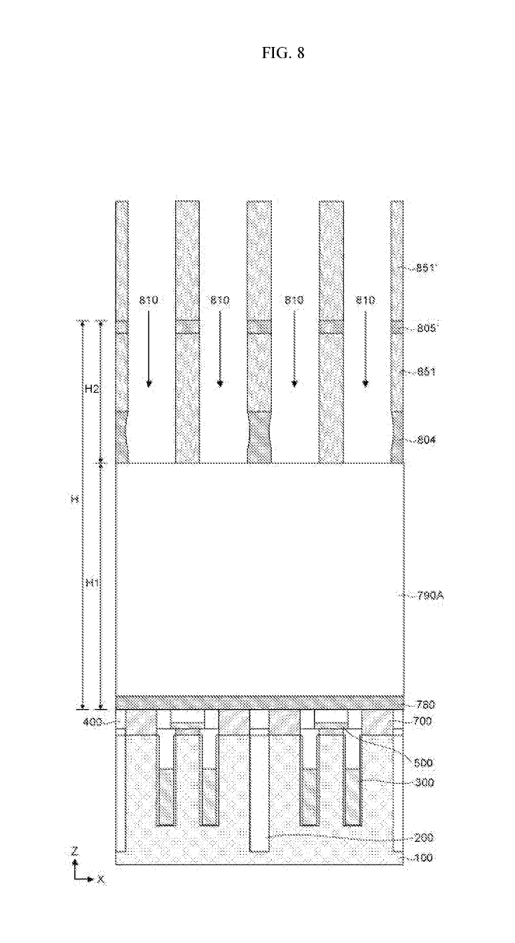

Next, a photoresist 91 is formed on top of the cylinder etching mask 850, and the desired pattern is formed in the photoresist 91 using photolithography. The portions of the photoresist 91 that are removed during this patterning process are the regions where the cylindrical holes 810 will be formed in a later process. Next, as illustrated in FIG. 8, the cylinder etching mask 850 is patterned using this patterned photoresist 91 as a mask, thereby exposing the regions of the BPSG film 790A where the cylindrical holes 810 will be formed. At this time, a portion of the Si₃N₄ film 804′ is also removed, thereby forming the first support film 804.

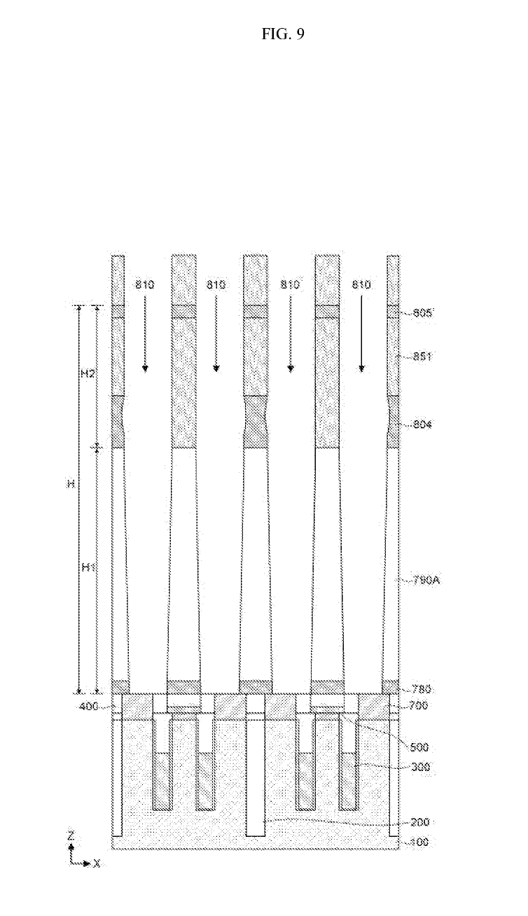

Next, as illustrated in FIG. 9, the BPSG film 790A and the stopper film 780 are etched using the patterned cylinder etching mask 850 as a mask to form the cylindrical holes 810 that expose the capacitive contact plugs 700. As illustrated in FIG. 9, etching the stopper film 780 and the BPSG film 790A (which have a collective height H1) in this manner reduces the aspect ratio of the holes in comparison with the prototype illustrated in FIG. 11. The polysilicon film 851 or the polysilicon film 851 and the first support film 804 add a height H2, which forms the remainder of the required height H.

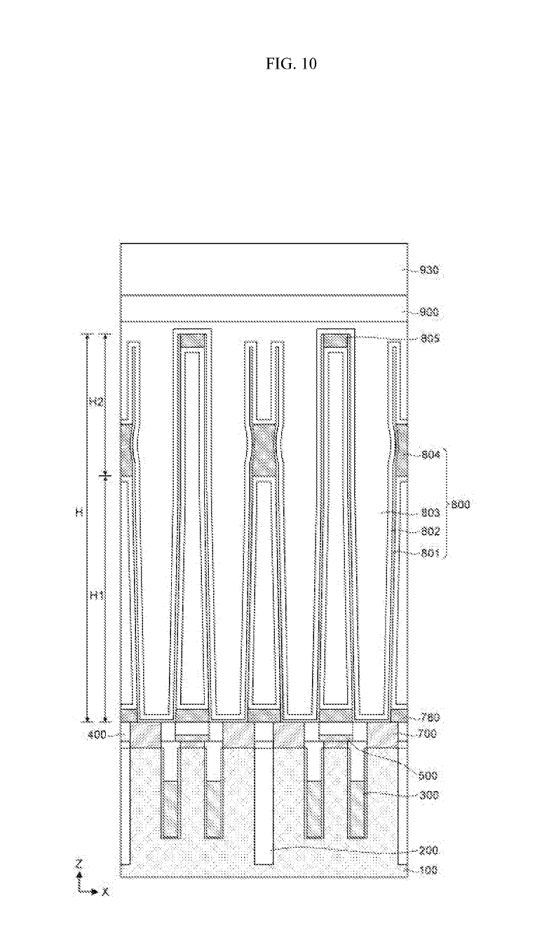

Next, as illustrated in FIG. 10, the entire polysilicon film 851′ is then removed, and the Si₃N₄ film 805′ is selectively removed to form the second support film 805. It is preferable that the second support film 805 be formed at different positions than the first support film 804 when viewed in a plan view. Then, the same process described in reference to FIG. 5 is performed, and a conductive layer is formed over the entire surface. Next, the conductive film covering the top surface of the polysilicon film 851 or the second support film 805 is removed, and the polysilicon film 851 and the BPSG film 790A are removed. As illustrated in FIG. 10, this process leaves conductive layers 801 having a height H from the capacitive contact plugs 700 at the bottom. The conductive layers 801 have an extremely large aspect ratio but are partially supported by the first support film 804 and the second support film 805 and are thereby prevented from collapsing.

Next, after forming a capacitive insulating film 802 and upper electrodes 803, an interlayer insulating film 900 and a protective insulating film 930 are formed to complete the semiconductor device according to the present embodiment.

In the method for manufacturing a semiconductor device according to the present embodiment, in addition to the effect described in Embodiment 1, the conductive layers 801 are also partially supported by the second support film 805, thereby more effectively preventing the conductive layers 801 from collapsing. Moreover, the height H required for the conductive layers 801 is defined by the top surface of the second support film 805, thereby making it possible to more accurately control the height H.

Preferable embodiments of the present invention were described above. However, the present invention is not limited to these embodiments. Various modifications can be made without departing from the spirit of the present invention, and such modifications are included within the scope of the present invention.

### DESCRIPTION OF REFERENCE CHARACTERS

91, 91 photoresist
100 semiconductor substrate
200 element isolation region
300 word line
400 interlayer insulating layer
500 bit line
700 capacitive contact plug
780 stopper film
790A, 790B BPSG film
801 conductive layer (lower electrode)
802 capacitive insulating film
803 upper electrode
804′, 805′ Si₃N₄ film
804 first support film
805 second support film
810 cylindrical hole
850 cylinder etching mask
851, 851′ polysilicon film
852 SiO₂ film
853 amorphous carbon film
854 multilayer SiN/SiON film
900 interlayer insulating film
930 protective insulating film

1. A method for manufacturing a semiconductor device, comprising:
forming a first insulating layer and a second insulating layer in order;
forming a mask layer on top of the second insulating layer;
forming openings in a prescribed pattern in the mask layer;
forming holes going through the second insulating layer to the first insulating layer in a thickness direction thereof, using the mask layer as a mask;
forming conductive layers contacting side surfaces of the mask layer, the second insulating layer, and the first insulating layer; and
removing the mask layer and the second insulating layer.

2. A method for manufacturing a semiconductor device, comprising:
forming a first insulating layer and a second insulating layer in order;
forming a first support layer on top of the second insulating layer;
forming, in a first pattern in the first support layer, openings that expose portions of the second insulating layer;
forming a first mask layer covering the first support layer and exposed portions of the second insulating layer;
forming, in the first mask layer and in a prescribed pattern, openings that overlap at least partially with the first pattern;
forming holes going through the first support layer and the second insulating layer to the first insulating layer in a thickness direction thereof, using the first mask layer as a mask;
forming conductive layers contacting side surfaces of the first mask layer, the first support layer, the second insulating layer, and the first insulating layer; and
removing the first mask layer and the second insulating layer.

3. The method of for claim 2, wherein the first insulating layer is formed using a material that contains at least silicon and nitrogen, and wherein the second insulating layer is formed using a material composed primarily of silicon oxide.

4. The method of claim 3, wherein the first support layer is formed using a material that contains at least silicon and nitrogen.

5. The method of claim 4, wherein the mask layer is formed using silicon.

6. The method of claim 2, wherein after the mask layer and the second insulating layer are removed, upper electrodes are formed covering the conductive layers with a capacitive insulating film disposed therebetween.

7. The method of claim 2, wherein the conductive layers are formed by forming a conductive layer covering the side surfaces of the mask layer, the second insulating layer, and the first insulating layer as well as the top surface of the mask layer and then selectively removing the conductive layer formed on the top surface of the mask layer.

8. The method of claim 6, further comprising:
forming an interlayer insulating layer;
forming openings for underlying contacts in the interlayer insulating layer; and
forming underlying contact plugs by filling the underlying contacts with a conductive material,
wherein the first insulating layer and the second insulating layer are formed in order covering the underlying contact plugs and the interlayer insulating layer.

9. A method for manufacturing a semiconductor device, comprising:
forming a first insulating layer and a second insulating layer in order;
forming a first support layer on top of the second insulating layer;
forming, in a first pattern in the first support layer, openings that expose portions of the second insulating layer;
forming a first mask layer covering the first support layer and exposed portions of the second insulating layer;
forming a second support layer on top of the first mask layer;
forming, in a second pattern in the second support layer, openings that expose portions of the first mask layer;
forming a second mask layer covering the second support layer and exposed portions of the first mask layer;
forming, in a prescribed pattern, openings that overlap at least partially with the first pattern and the second pattern and that go through the second mask layer and the second support layer to the first mask layer in a thickness direction thereof;
forming holes going through the first support layer and the second insulating layer to the first insulating layer in a thickness direction thereof, using the second mask layer as a mask;
forming conductive layers contacting side surfaces of the second support layer, the second mask layer, the first mask layer, the first support layer, the second insulating layer, and the first insulating layer; and
removing the second mask layer, the first mask layer, and the second insulating layer.
